(19) United States
(12) Patent Application Publication
(10) Pub. No.: US 2026/0143720 A1
(43) Pub. Date: May 21, 2026

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Junho Song, Suwon-si (KR); Gwangguk An, Suwon-si (KR); Zhe Wu, Suwon-si (KR)

(21) Appl. No.: 19/269,397

(22) Filed: Jul. 15, 2025

(30) Foreign Application Priority Data
Nov. 18, 2024 (KR) 10-2024-0164425

(51) Int. Cl. H10B 63/00

(52) U.S. Cl. CPC H10B 63/24

(57) ABSTRACT

An example embodiment of the present disclosure provides a method of manufacturing a semiconductor memory device, including: separating a memory stack including a selector layer into stack lines or memory cell pillars using a mask pattern; selectively depositing a dielectric layer on a surface of the mask pattern to fill a gap between the mask patterns and form an air gap between the stack lines or the memory cell pillars; and polishing and removing the mask patterns and forming a gap-covering dielectric covering the air gap from the dielectric layer.

### CROSS-REFERENCE TO RELATED APPLICATION(S)

This application claims benefit of priority under 35 U.S.C. § 119 to Korean Patent Application No. 10-2024-0164425 filed on Nov. 18, 2024, in the Korean Intellectual Property Office, the disclosure of which is incorporated herein by reference in its entirety.

### BACKGROUND

The present disclosure relates generally to a semiconductor memory device and a method of manufacturing the same.

In a data storage system requiring data storage, a semiconductor memory device capable of storing a large amount of data is required. Accordingly, a method of increasing the data storage capacity of a semiconductor memory device has been researched. For example, as one method of increasing the data storage capacity of a semiconductor memory device, a semiconductor device including memory cells arranged three-dimensionally instead of memory cells arranged two-dimensionally has been proposed.

### SUMMARY

An aspect of the present disclosure is to provide a semiconductor memory device having improved integration and reliability.

An aspect of the present disclosure is to provide a method of manufacturing a semiconductor memory device having improved integration and reliability.

In order to solve the above-described aspects, an example embodiment of the present disclosure provides a method of manufacturing a semiconductor device including: forming a memory stack including a selector layer; forming a plurality of first mask patterns on the memory stack, the plurality of first mask patterns each extending in a first direction and separated from each other in a second direction, intersecting the first direction; forming a plurality of stack lines extending in the first direction, by etching the memory stack using the plurality of first mask patterns; selectively depositing a first dielectric layer on surfaces of the plurality of first mask patterns so that a first air gap between the plurality of stack lines is formed by filling a gap between the plurality of first mask patterns, the first dielectric layer having a portion extending to be lower than a bottom level of the first mask pattern; removing the plurality of first mask patterns and a portion of the first dielectric layer between the plurality of first mask patterns from upper surfaces of the plurality of stack lines, the extending portion of the first dielectric layer being provided as a first gap-covering dielectric on the first air gap; forming an upper conductive layer on the plurality of stack lines and the first gap-covering dielectric; forming a plurality of second mask patterns on the upper conductive layer, the plurality of second mask patterns each extending in the second direction and separated from each other in the first direction; forming a plurality of memory cell pillars and a plurality of upper conductive lines by etching each of the plurality of stack lines and the upper conductive layer, using the plurality of second mask patterns, the plurality of upper conductive lines each connecting the plurality of memory cell pillars in the second direction; selectively depositing a second dielectric layer on surfaces of the plurality of second mask patterns and surfaces of the plurality of upper conductive lines so that a second air gap extending in the second direction is formed between the plurality of memory cell pillars by filling a gap between the plurality of second mask patterns and a gap between the plurality of upper conductive lines; and removing the plurality of second mask patterns and a portion of the second dielectric layer between the plurality of second mask patterns, a portion of the second dielectric layer between the plurality of upper conductive lines being provided as a second gap-covering dielectric covering the second air gap.

An example embodiment of the present disclosure provides a method of manufacturing a semiconductor device including: forming a lower conductive layer on a substrate, and forming a memory stack including a selector layer on the lower conductive layer; forming a plurality of first mask patterns on the memory stack, the plurality of first mask patterns each extending in a first direction and separated from each other in a second direction, intersecting the first direction; forming a plurality of stack lines and a plurality of lower conductive lines, by etching the plurality of memory stacks and the lower conductive layer using the plurality of first mask patterns; forming an encapsulation between the plurality of stack lines and between the plurality of lower conductive lines; removing the plurality of first mask patterns so as to expose upper surfaces of the plurality of stack lines; forming an upper conductive layer on the plurality of stack lines and the encapsulation; forming a plurality of second mask patterns on the upper conductive layer, the plurality of second mask patterns each extending in the second direction and separated from each other in the first direction; forming a plurality of memory cell pillars and a plurality of upper conductive lines, by etching each of the plurality of stack lines together with the upper conductive layer using the plurality of second mask patterns, each of the plurality of upper conductive lines connecting the plurality of memory cell pillars in the second direction; selectively depositing a dielectric layer on surfaces of the plurality of second mask patterns and surfaces of the plurality of upper conductive lines so that an air gap extending in the second direction is formed between the plurality of memory cell pillars by filling a gap between the plurality of second mask patterns and a gap between the plurality of upper conductive lines; and removing the plurality of second mask patterns and a portion of the dielectric layer between the plurality of second mask patterns, a portion of the dielectric layer between the plurality of upper conductive lines being provided as a gap-covering dielectric on the air gap.

According to an example embodiment, a method of manufacturing a semiconductor device includes: forming a memory stack including a selector layer; forming a plurality of first mask patterns on the memory stack, the plurality of first mask patterns each extending in a first direction and separated from each other in a second direction, intersecting the first direction; forming a plurality of stack lines extending in the first direction, by etching the memory stack using the plurality of first mask patterns; selectively depositing a dielectric layer on surfaces of the plurality of first mask patterns so as to fill a gap between the plurality of first mask patterns and form an air gap between the plurality of stack lines, the dielectric layer having a portion extending lower than a bottom level of the mask pattern; removing the plurality of first mask patterns and a portion of the dielectric layer between the plurality of first mask patterns, from respective upper surfaces of the plurality of stack lines, the extending portion of the dielectric layer being provided as a gap-covering dielectric on the air gap; forming an upper conductive layer on the plurality of stack lines and the gap-covering dielectric; forming a plurality of second mask patterns on the upper conductive layer, the plurality of second mask patterns each extending in the second direction and separated from each other in the first direction; forming a plurality of memory cell pillars and a plurality of upper conductive lines, by etching each of the plurality of stack lines together with the upper conductive layer using the plurality of second mask patterns, each of the plurality of upper conductive lines connecting the plurality of memory cell pillars in the second direction; and forming an encapsulation between the plurality of upper conductive lines and between the plurality of memory cell pillars.

An example embodiment of the present disclosure provides a semiconductor device including: a substrate; first conductive lines extending in a first direction, on the substrate; second conductive lines extending in a second direction intersecting the first direction, on the first conductive lines; a plurality of memory cell pillars at an intersection of the first conductive lines and the second conductive lines, between the first conductive lines and the second conductive lines, and respectively including a selector layer; and a gap-covering dielectric on side surfaces and lower surfaces of the second conductive lines so that an air gap is formed between the plurality of memory cell pillars, and the gap-covering dielectric includes first gap-covering dielectrics respectively disposed on portions of lower surfaces of the second conductive lines between the plurality of memory cell pillars in the second direction and first gap-covering dielectrics extending between the second conductive lines in the second direction, and the gap-covering dielectric does not extend to a side surface of the selector layer or is formed to be 30 angstroms (Å) or less even if the gap-covering dielectric extends.

An example embodiment of the present disclosure provides a semiconductor device, comprising: a substrate; first conductive lines extending in a first direction, on the substrate; second conductive lines extending in a second direction, intersecting the first direction, on the first conductive lines; a plurality of memory cell pillars disposed at an intersection of the first conductive lines and the second conductive lines, between the first conductive lines and the second conductive lines, each of the plurality of memory cell pillars including a selector layer; and a gap-covering dielectric disposed on side surfaces and lower surfaces of the second conductive lines so that an air gap is formed between the plurality of memory cell pillars, wherein the gap-covering dielectric includes first gap-covering dielectrics disposed on portions of lower surfaces of the second conductive lines disposed between the plurality of memory cell pillars in the second direction and second gap-covering dielectrics extending between the second conductive lines in the second direction, and the gap-covering dielectric does not extend to a side surface of the selector layer or has a thickness of 30 Å or less even if the gap-covering dielectric extends.

In one example embodiment, each of the plurality of memory cell pillars includes a first electrode layer connected to the first conductive line and a second electrode layer connected to the second conductive line, and the selector layer is disposed between the first electrode layer and the second electrode layer.

In one example embodiment, the semiconductor device further comprises a filling insulating pattern between the first conductive lines, wherein an upper surface of the filling insulating pattern has a recess extending in the first direction, and a bottom dielectric disposed on the upper surface of the filling insulating pattern and including the same material as the first gap-covering dielectric.

In one example embodiment, the semiconductor device further comprises a bottom dielectric on a portion of the substrate between the first conductive lines and on side surfaces of the first conductive lines, and including the same material as the first gap-covering dielectric.

In one example embodiment, the semiconductor device further a sidewall dielectric including the same material as the first gap-covering dielectric and disposed on side surfaces of the plurality of memory cell pillars in the second direction, wherein the bottom dielectric has a thickness greater than a thickness of the sidewall dielectric on a side surface of the selector layer.

### BRIEF DESCRIPTION OF DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a schematic perspective view illustrating a semiconductor memory device according to an example embodiment of the present disclosure;

FIGS. 2A and 2B are schematic cross-sectional views taken along lines I-I′ and II-II′ of the semiconductor memory device illustrated in FIG. 1, respectively;

FIG. 3A is a schematic plan view illustrating the semiconductor memory device illustrated in FIGS. 1, 2A and 2B, and FIG. 3B is a schematic plan view taken along line III-III′ of the semiconductor memory device illustrated in FIGS. 2A and 2B;

FIGS. 4A to 4I are schematic perspective views for each main process describing intermediate processes in an example method of manufacturing the semiconductor memory device illustrated in FIG. 1;

FIGS. 5A to 5C are schematic cross-sectional views for each main process describing intermediate processes in a first selective deposition process introduced in FIGS. 4D and 4E;

FIGS. 6A to 6C are schematic cross-sectional views for each main process describing intermediate processes in a secondary selective deposition process introduced in FIGS. 4H and 4I;

FIGS. 7A and 7B are schematic cross-sectional views illustrating a semiconductor memory device according to an example embodiment of the present disclosure;

FIGS. 8A and 8B are schematic cross-sectional views illustrating a semiconductor memory device according to an example embodiment of the present disclosure;

FIGS. 9A and 9B are schematic cross-sectional views illustrating a semiconductor memory device according to an example embodiment of the present disclosure;

FIGS. 10A to 10F are schematic perspective views for each main process describing intermediate processes in an example method of manufacturing the semiconductor memory device illustrated in FIGS. 9A and 9B;

FIGS. 11A and 11B are schematic cross-sectional views illustrating a semiconductor memory device according to an example embodiment of the present disclosure; and

FIGS. 12A and 12B are schematic cross-sectional views respectively illustrating a semiconductor memory device according to an example embodiment of the present disclosure.

### DETAILED DESCRIPTION

Hereinafter, example embodiments of the present disclosure will be described with reference to the accompanying drawings.

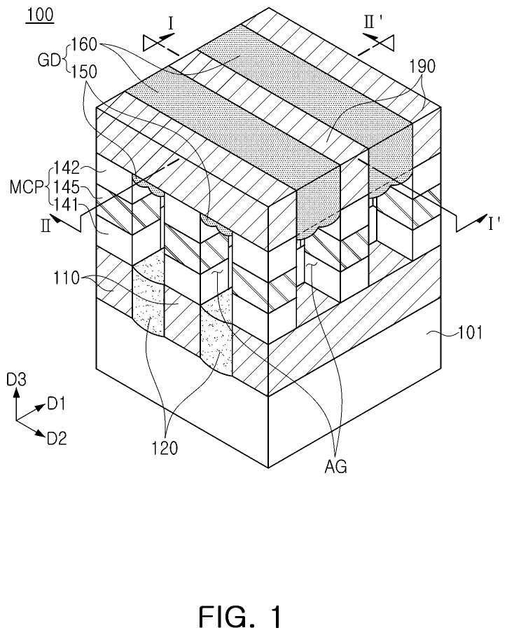

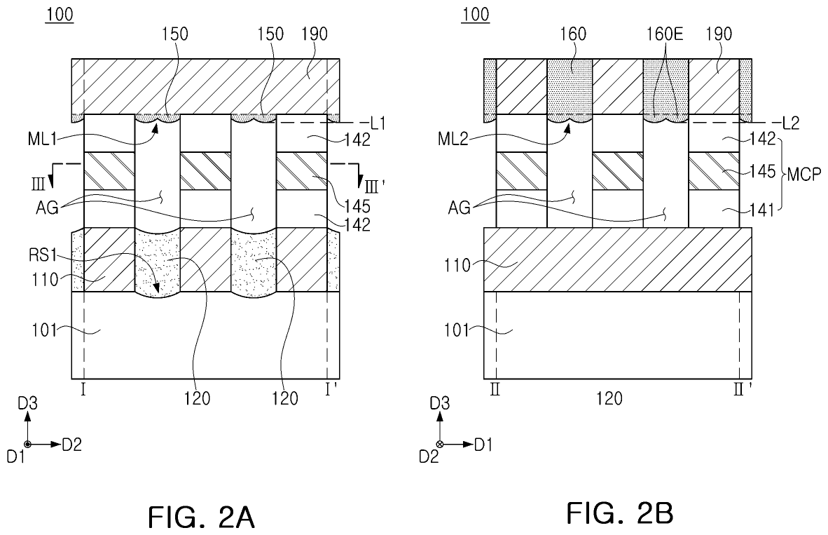

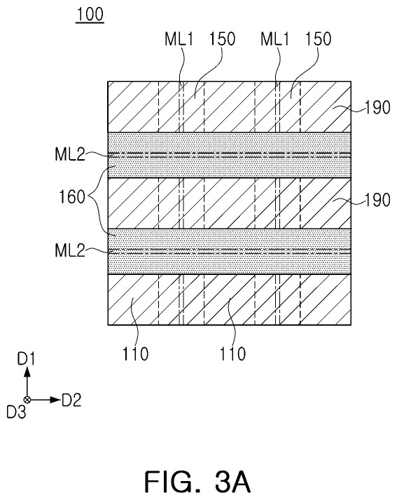

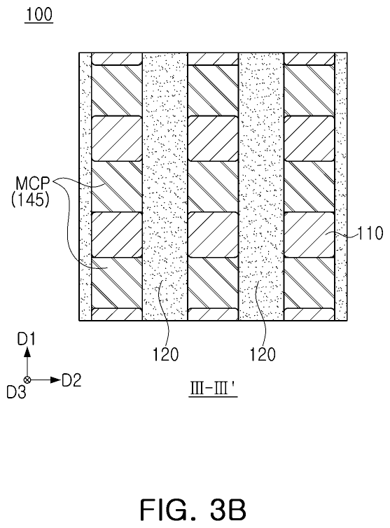

FIG. 1 is a schematic perspective view illustrating a semiconductor memory device according to an example embodiment of the present disclosure, FIGS. 2A and 2B are schematic cross-sectional views taken along lines I-I′ and II-II′ of the semiconductor memory device illustrated in FIG. 1, respectively, FIG. 3A is a schematic plan view illustrating the semiconductor memory device illustrated in FIG. 1 and FIG. 2, and FIG. 3B is a schematic plan view taken along line III-III′ of the semiconductor memory device illustrated in FIG. 2.

Referring to FIGS. 1 to 3B, a semiconductor memory device 100 according to an example embodiment may include first conductive lines 110 extending in a first direction D1 on a substrate 101, second conductive lines 190 extending in a second direction D2 intersecting the first direction D1 on the first conductive lines 110, a plurality of memory cell pillars MCP illustrated between the first conductive lines 110 and the second conductive lines 190, and a gap-covering dielectric GD forming an air gap AG between the plurality of memory cell pillars MCP. The first and second directions D1 and D2 may be parallel to a surface of the substrate 101 (e.g., horizontal directions).

In the semiconductor device 100, memory cell pillars MCP may be disposed at an intersection of the first conductive lines 110 and the second conductive lines 190. The semiconductor device 100 may be a memory element having a three-dimensional cross point array structure, and may be, for example, a selector-only memory (SOM).

The substrate 101 may have an upper surface extending in the first direction D1 and the second direction D2. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer. In some example embodiments, the semiconductor device 100 may further include an interlayer insulating layer (not illustrated) on the substrate 101. The interlayer insulating layer may be disposed between the substrate 101 and the first conductive line 110 to electrically isolate the substrate 101 and the first conductive line 110. For example, the interlayer insulating layer may include an oxide such as silicon oxide and/or a nitride such as silicon nitride.

In terms of driving the semiconductor device 100, the first conductive lines 110 may correspond to one of a word line or a bit line (e.g., a word line), and the second conductive lines 190 may correspond to the other one of the word line or the bit line (e.g., a bit line). Each of the first conductive lines 110 and the second conductive lines 190 may be formed of a metal, a conductive metal nitride, a conductive metal oxide, or combinations thereof. For example, each of the first conductive lines 110 and the second conductive lines 190 may be formed of W, WN, Au, Ag, Cu, Al, TiAlN, Ir, Pt, Pd, Ru, Zr, Rh, Ni, Co, Cr, Sn, Zn, ITO, alloys thereof, or combinations thereof. The first and second conductive lines 110 and 190 may include the same material or may include different materials relative to each other. For example, each of the first and second conductive lines 110 and 190 may include tungsten (W). In some example embodiments, each of the first conductive lines 110 and the second conductive lines 190 may include a metal film and a conductive barrier layer partially or entirely covering the metal film. The term “covering” (or “cover,” or like terms), as may be used herein, is intended to broadly refer to an element, structure or layer that is on or over another element, structure or layer, either directly or with one or more other intervening elements, structures or layers therebetween. The conductive barrier layer may be formed of, for example, Ti, TiN, Ta, TaN, or combinations thereof.

A filling insulating pattern 120 may be provided between the first conductive lines 110 on the substrate 101. The filling insulating pattern 120 may fill a space between the first conductive lines 110 spaced apart from each other. The term “fill” (or “fills,” or like terms) is intended to refer to either completely filling a defined space (e.g., the space between the first conductive lines 110) or partially filling the defined space; that is, the defined space need not be entirely filled but may, for example, be partially filled or have voids or other spaces throughout. The filling insulating pattern 120 may be formed of, for example, at least one of silicon oxide, silicon oxynitride, or combinations thereof.

Each of the plurality of memory cell pillars MCP may include a first electrode layer 141 connected to the first conductive line 110, a second electrode layer 142 connected to the second conductive line 190, and a selector layer 145 between the first electrode layer 141 and the second electrode layer 142. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

The first electrode layer 141 and the second electrode layer 142 may be provided as paths through which current flows and may include a conductive material. For example, each of the first electrode layer 141 and the second electrode layer 142 may include carbon (C). However, the present disclosure is not limited thereto, and the first electrode layer 141 and the second electrode layer 142 may be formed of a metal, a conductive metal nitride, a conductive metal oxide, or combinations thereof. For example, in addition to carbon, one or more of titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tungsten (W), or tungsten nitride (WN) may be selected.

The selector layer 145 adopted in an example embodiment may have a memory characteristic for memorizing (i.e., storing) a resistance state and a selector characteristic for switching at the same time. Accordingly, the semiconductor device 100 may not further include a separate switching element or a separate resistive layer in addition to the selector layer 145. In some example embodiments, the selector layer 145 may be a single material layer, but the present disclosure is not limited thereto. When the selector layer 145 has a large cross-sectional thickness, an operating voltage may increase, and when the selector layer 145 is thin, the leakage current may increase. For example, the thickness of the selector layer 145 may be in a range of about 10 nm to about 30 nm. The selector layer 145 may include a material layer in which a resistance thereof may change depending on the magnitude of the voltage applied to both ends thereof. The selector layer 145 may include an Ovonic Threshold Switching (OTS) material. For example, the selector layer 145 may include a phase change material in which a resistance thereof changes depending on temperature. In some example embodiments, the selector layer 145 may include at least one of sulfur(S), selenium (Se), tellurium (Te), or arsenic (As).

In an example embodiment, the selector layer 145 may include a chalcogenide material. Accordingly, the selector layer 145 may include, for example, at least one of sulfur(S), selenium (Se) or tellurium (Te), which are Group 16 elements. Alternatively, the selector layer 145 may include at least one of silicon (Si) or germanium (Ge), which are Group 14 elements, and arsenic (As) or antimony (Sb), which are Group 15 elements, or may include the above-described element in addition to the Group 16 elements. In some example embodiments, the selector layer 145 may further include a metallic material. In some example embodiments, the selector layer 145 may further include at least one additional element of boron (B), carbon (C), nitrogen (N), or oxygen (O).

For example, the selector layer 145 may be formed as a single layer or multilayer including at least one of binary materials such as GeSe, GeS, AsSe, AsTe, AsS SiTe, SiSe, SiS, GeAs, SiAs, SnSe, SnTe, and the like, ternary materials such as GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, and the like, quaternary materials such as GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, GeAsTeZn, and the like, pentamaterials such as GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSeAlSn, GeAsSeTlZn, GeAsSeTlSn, GeAsSeZnSn, and the like, or hexamaterials such as GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, GeAsSeSAlSn, and the like.

The gap-covering dielectric GD may be disposed on side surfaces and lower surfaces of the second conductive lines 190 so that the air gap AG is formed between the plurality of memory cell pillars MCP. In an example embodiment, the gap-covering dielectric GD may include a first gap-covering dielectric 150 and a second gap-covering dielectric 160 having different deposition times and formation positions.

Referring to FIGS. 2A and 3A, the first gap-covering dielectric 150 may include patterns respectively disposed on portions of lower surfaces of the second conductive lines 190 disposed between the plurality of memory cell pillars MCP in the second direction D2. The first gap-covering dielectric 150 may be formed so as to connect opposing side surfaces of memory cell pillars MCP adjacent to each other in the second direction D2, among the plurality of memory cell pillars MCP.

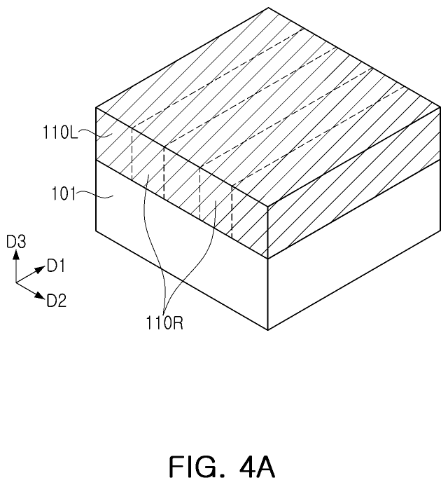

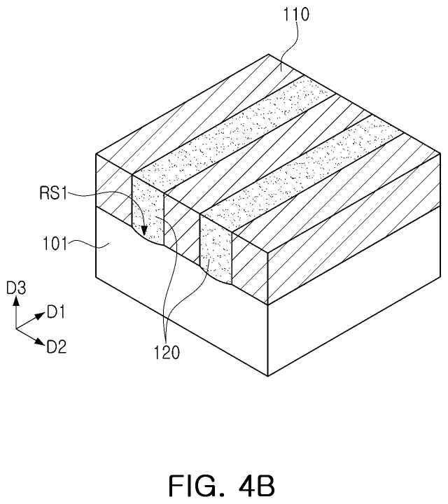

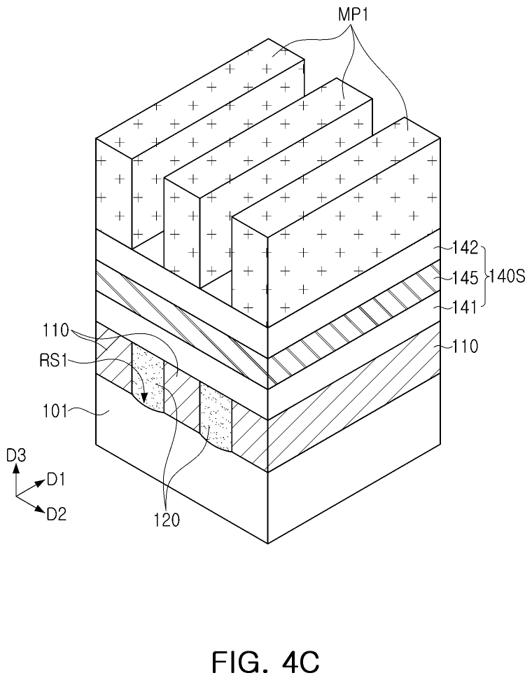

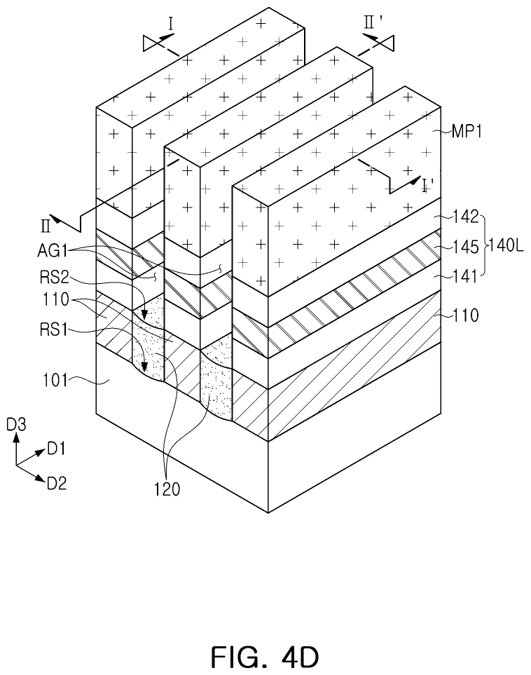

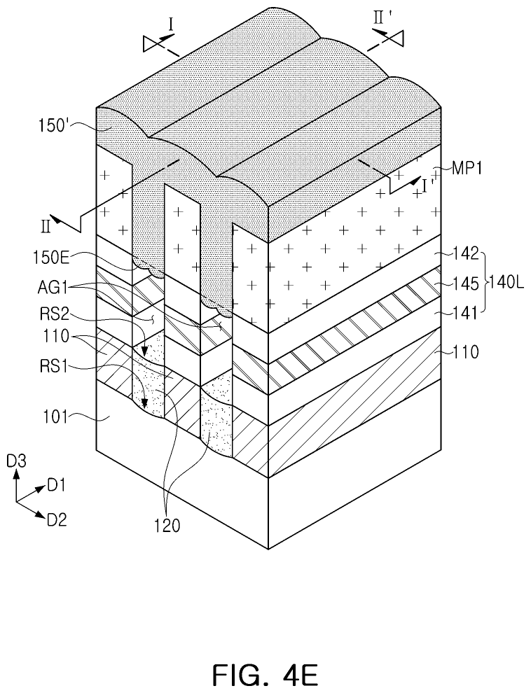

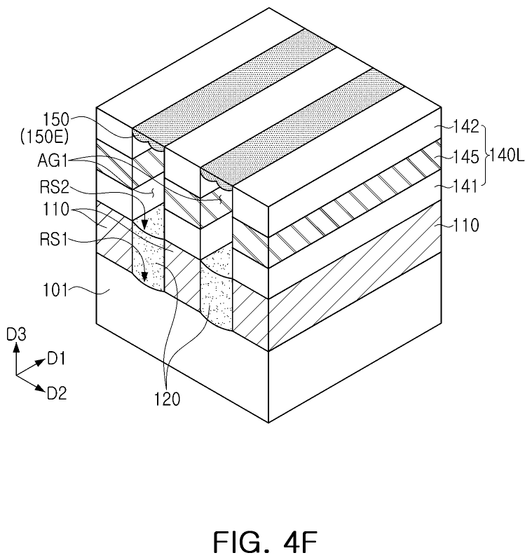

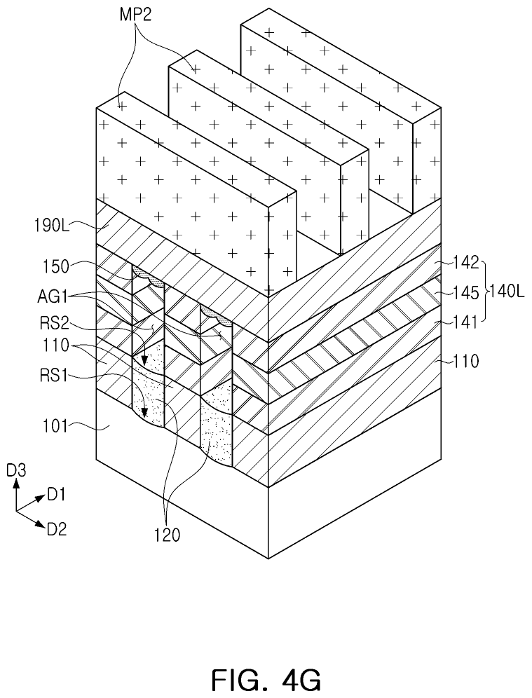

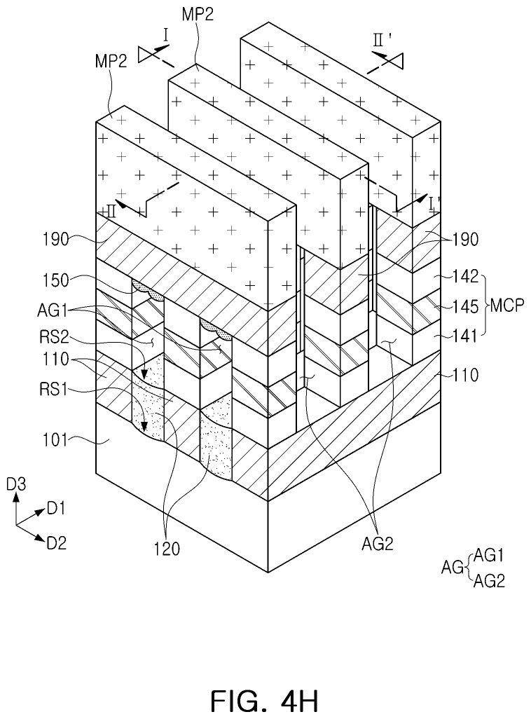

In processes prior to forming the second conductive line 190 during the manufacturing process of the semiconductor memory device 100 (see FIGS. 4D to 4F), the selectively grown dielectrics on the opposing side surfaces of the first mask pattern (“MP1” in FIG. 4E) on the plurality of memory cell pillars MCP may be merged with each other, and in this case, a first gap-covering dielectric 150 may be obtained from an extending portion overgrown to an upper region of the second electrode layer 142. In the process of forming a subsequent second conductive line 190, the first gap-covering dielectric 150 may be used as a cover layer protecting exposed side surfaces of the stack line (“SL” in FIG. 4D). In an example embodiment, a bottom level L1 of the first gap-covering dielectric 150 may be lower than a level of a bottom of the first conductive lines 190, in a third direction D3 relative to the surface of the substrate 101 as a reference, and may include a first merging line ML1 having a concave shape extending in the first direction.

The second gap-covering dielectric 160 may extend in the second direction D2 between the second conductive lines 190. The second gap-covering dielectric 160 may fill a gap between the second conductive lines 190, similarly to the filling insulating patterns 120. However, the second gap-covering dielectric 160 may be formed by merging selectively grown dielectrics with each other on opposing side surfaces of adjacent second conductive lines 190 and opposing side surfaces of adjacent second mask patterns (“MP2” in FIG. 4H), similarly to the first gap-covering dielectric layer 150.

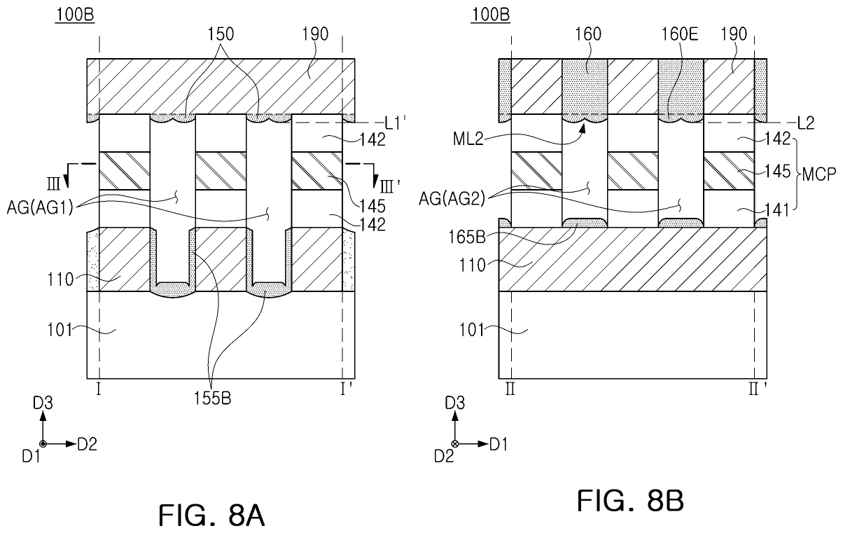

In an example embodiment, as illustrated in FIG. 2B, the second gap-covering dielectric 160 may have an extending portion 160E overgrown to the upper region of the second electrode layer 142. Even if the extending portion 160E is absent or small, when the second gap-covering dielectric 160 fills the gap between the second conductive lines 190, the second gap-covering dielectric 160 may be suitably used as a cover layer. In an example embodiment, a bottom level L2 of the extending portion 160E of the second gap-covering dielectric 160 may be lower than lower surfaces of the second conductive lines 190, in the third direction D3 relative to the surface of the substrate 101, and may be similar to the bottom level L1 of the first gap-covering dielectric 150. In some example embodiments, the bottom level L2 of the extending portion 160E of the second gap-covering dielectric 160 may be different from a bottom level L1 of the first gap-covering dielectric 150 (see FIGS. 8A and 8B). The first gap-covering dielectric 150 and the second gap-covering dielectric 160 may be connected to each other, but in some example embodiments, the first gap-covering dielectric 150 and the second gap-covering dielectric 160 may be separated from each other.

The first gap-covering dielectric 150 and the second gap-covergap-covering dielectric 160 may include a material capable of selective deposition. In some example embodiments, the first gap-covergap-covering dielectric 150 and the second gap-covergap-covering dielectric 160 may be formed using a seed layer capable of selective deposition in a region rich in hydroxyl groups (—OH). At least one of the first gap-covergap-covering dielectric 150 or the second gap-covergap-covering dielectric 160 may be formed of amorphous silicon, silicon nitride, or aluminum oxide. The first gap-covergap-covering dielectric 150 and the second gap-covering dielectric 160 may include the same material, but since the first gap-covering dielectric 150 and the second gap-covering dielectric 160 are formed by different deposition processes, in some example embodiments, the first gap-covering dielectric 150 and the second gap-covering dielectric 160 may be formed of different materials.

The semiconductor device 100 according to an example embodiment may have the air gap AG between the plurality of memory cell pillars MCP by the gap-covering dielectric GD, and the air gap AG may prevent interference between adjacent memory cell pillars MCP. The air gap AG may be formed over almost an entire side surface of the selector layer 145 corresponding to an active region (e.g., a selector layer, an information storage layer or a switching element). In an example embodiment, the air gap AG may extend over a side surface of the first electrode layer 141 and a portion of a side surface region of the second electrode layer 142.

As described above, since the gap-covering dielectric GD is formed using a selective deposition process according to a deposited surface, direct deposition on side surfaces of the memory cell pillar MCP may barely occur. When the first and second gap-covering dielectrics 150 and 160, respectively, are formed, the dielectric may barely be deposited on the side surfaces of the memory cell pillar MCP.

Referring to FIGS. 3A and 3B along with FIG. 2A and FIG. 2B, in an example embodiment, the dielectric may not be present on the side surfaces of the memory cell pillar MCP. For example, side surfaces of the selector layer 145 may be exposed to the air gap AG together with a portion of the first electrode layer 141 and the second electrode layer 142. The extending portions 150E and 160E of the first and second gap-covering dielectrics 150 and 160, respectively, may also be understood as overgrown portions in other regions (e.g., side surfaces of the first and second mask patterns) rather than being directly deposited on side surfaces of the second electrode layer 142. In some example embodiments, depending on the selectivity of the selective deposition, a side wall dielectric layer (“152” or “162” of FIGS. 8A and 8B) may also be formed on the side surfaces of the memory cell pillar MCP when the first and second gap-covering dielectrics 150 and 160 are formed, but even if the side wall dielectric layer is present, the side wall dielectric layer may have a significantly small cross-sectional thickness (e.g., less than about 30 Å) (see FIGS. 8A and 8B).

In this manner, by providing the first and second gap-covering dielectrics 150 and 160, respectively, to the side surface and some of the lower surfaces of the second conductive lines 190, the air gap AG may be provided between the memory cell pillars MCP, thus suppressing crosstalk between the memory cell pillars MCP.

FIGS. 4A to 4I are schematic perspective views for each main process depicting intermediate processes in an example method of manufacturing a semiconductor memory device illustrated in FIG. 1.

Referring to FIG. 4A, a first conductive layer 110L may be formed on a substrate 101.

The substrate 101 may include a semiconductor substrate such as silicon, germanium, or silicon-germanium. The first conductive layer 110L (also referred to as a ‘lower conductive layer’) for the first conductive lines (also referred to as ‘lower conductive lines’) may be formed on an upper surface of the substrate 101. The first conductive layer 110L may include W, WN, Au, Ag, Cu, Al, TiAlN, Ir, Pt, Pd, Ru, Zr, Rh, Ni, Co, Cr, Sn, Zn, ITO, alloys thereof, or combinations thereof. Some line patterns 110R of the first conductive layer 110L may be removed by an etching process. Accordingly, first conductive lines 110 (see FIG. 4B) extending in the first direction D1 from the first conductive layer 110L may be obtained.

In some example embodiments, an interlayer insulating layer (not illustrated) may be disposed between the substrate 101 and the first conductive layer 110L. For example, the interlayer insulating layer may include an oxide such as silicon oxide and/or a nitride such as silicon nitride.

Referring to FIG. 4B, first conductive lines 110 may be formed from the first conductive layer 110L (see FIG. 4A), and filling insulating patterns 120 may be formed between the first conductive lines 110.

As described above in connection with FIG. 4A, by etching some line patterns 110R of the first conductive layer 110L, first conductive lines 110 extending in the first direction D1 from the first conductive layer 110L and separated from each other in the second direction may be formed. By this etching process, a first recess RS1 may be formed in a portion between the first conductive lines 110 on the upper surface of the substrate 101. In some example embodiments, a conductive barrier layer may be formed on an upper surface and side surfaces of the first conductive lines 110. For example, the conductive barrier layer may include Ti, TiN, Ta, TaN, or combinations thereof, although embodiments are not limited thereto.

Next, a filling insulating pattern 120 may be formed between the first conductive lines 110 on the substrate 101. An insulating material layer may be formed to cover the first conductive lines 110 so as to fill the first conductive lines 110. For example, the insulating material layer may be formed of at least one of silicon oxide, silicon oxynitride, and combinations thereof. Then, a flattening process such as Chemical Mechanical Polishing (CMP) may be performed so that the upper surfaces of the first conductive lines 110 is exposed, thereby forming filling insulating patterns 120 between the first conductive lines 110, as illustrated in FIG. 4B. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Referring to FIG. 4C, a memory stack 140S may be formed on the first conductive lines 110 and the filling insulating patterns 120, and first mask patterns MP1 may be formed on the memory stack 140S.

A memory stack 140S may be formed by sequentially forming the first electrode layer 141, the selector layer 145 and the second electrode layer 142 on flattened upper surfaces of the first conductive lines 110 and the filling insulating patterns 120, stacked in the third direction D3. The first mask patterns MP1 may have a pattern corresponding to the first conductive lines 110. The first mask patterns MP1 may extend in the first direction D1 and may be separated from each other in the second direction D2. The first mask patterns MP1 may include two or more layers. For example, the first mask patterns MP1 may include a lower layer such as silicon nitride and a hard mask layer such as silicon oxide or silicon carbonate, and may be patterned using a photoresist process.

Next, referring to FIG. 4D, a plurality of stack lines 140L may be formed from the memory stack 140S using the first mask patterns MP1.

An etching process using the first mask patterns MP1 may be performed to form the stack lines 140L extending in the first direction D1 and separated from each other in the second direction D2. By this etching process, the filling insulating patterns 120 may be opened again, and a second recess RS2 may be formed on upper surfaces of the filling insulating patterns 120 by additional etching.

Referring to FIG. 4E, a first dielectric layer 150′ may be selectively deposited on surfaces of a plurality of first mask patterns MP1.

In an example embodiment, the first dielectric layer 150′ may be formed by a selective deposition process that is advantageous in direct deposition on the surfaces (upper surfaces and side surfaces) of the first mask patterns MP1. The selective deposition adopted in this example embodiment may cause little deposition on exposed side surfaces of the stack lines 140L. Accordingly, the deposition may be performed to cover the first mask patterns MP1 while filling the gap between the first mask patterns MP1.

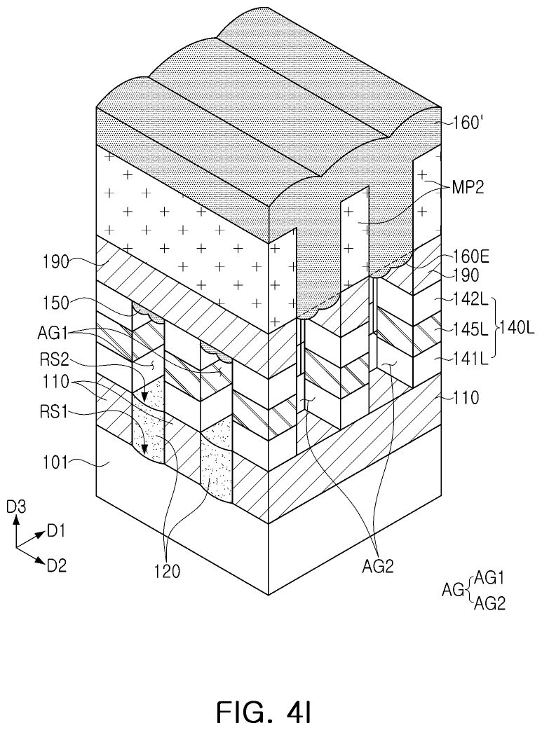

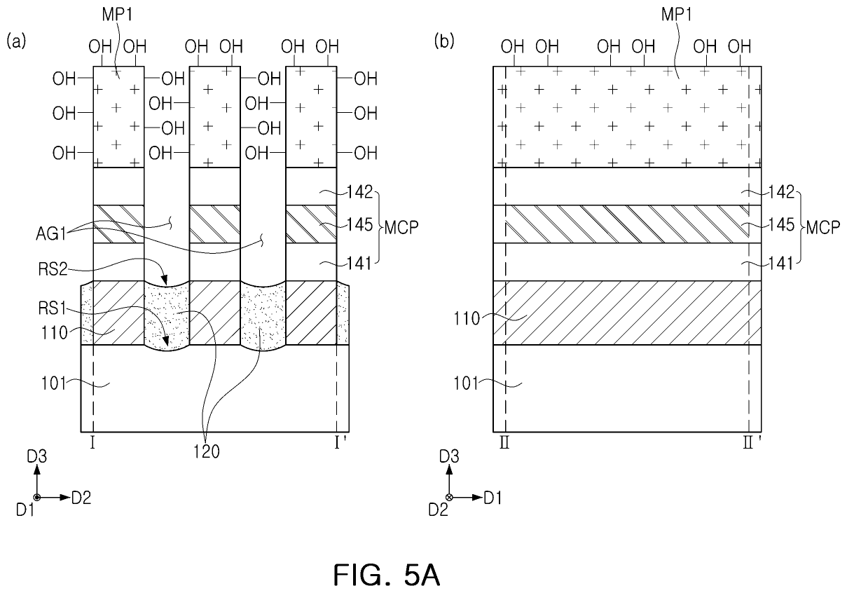

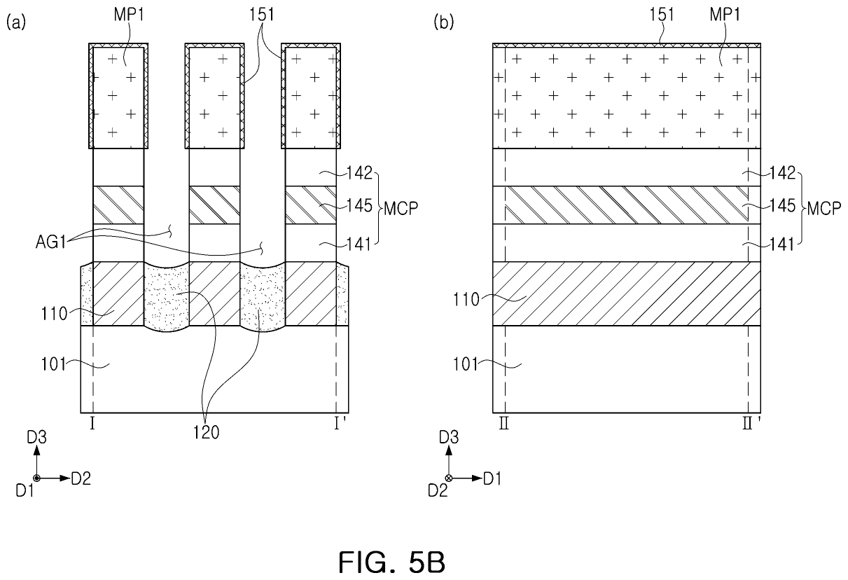

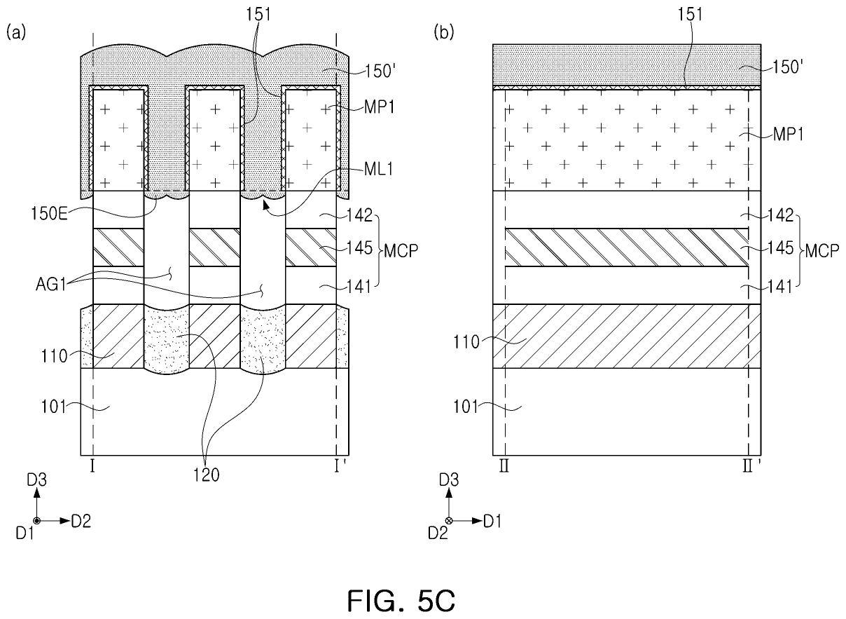

An example of the first selective deposition process that may be adopted in the present process may be described in detail with reference to FIGS. 5A to 5C. FIGS. 5A and 5C may be understood as schematic cross-sections of I-I′ and II-II′ of FIGS. 4D and 4E, respectively. This process is described as a selective deposition process in which the first dielectric layer 150′ is amorphous silicon.

As illustrated in FIG. 5A, in the etching process and subsequent processes of forming the stack lines 140L, hydroxyl groups (—OH) may be adsorbed on surfaces of the first mask patterns MP1 such as silicon oxide. In contrast, due to differences in the constituent materials, hydroxyl groups (—OH) may be adsorbed in small amounts or hardly adsorbed on side surfaces of the stack lines 140L.

As illustrated in FIG. 5B, a first seed layer 151 having different deposition rates depending on an amount of the hydroxyl groups may be selectively deposited; that is, the deposition rate of the first seed layer 151 is a function of the hydroxyl groups. The first seed layer 151 may be formed on a surface of the first mask patterns MP1 rich in hydroxyl groups (—OH). In an example embodiment, the first seed layer 151 may include a precursor for depositing amorphous silicon. In some example embodiments, the first seed layer 151 may include a silane precursor, an amine precursor, or an aminosilane precursor. For example, the silane precursor may include monochlorosilane (MCS), dichlorosilane (DCS), or hexachlorodisilane (HCDS), diiodosilane (DIS). For example, the amine precursor may include trisilylamine. For example, the aminesilane precursor may include diisopropylaminosilane (DIPAS; LTO520), diisopropylaminodisilane (DIPADS), bis(t-butylamino)silane (BTBAS), bis(diethylamino)silane (BDEAS), or bis(ethylmethylamino)silane (BEMAS).

As illustrated in FIG. 5C, the first dielectric layer 150′ which is amorphous silicon may be selectively deposited using thermal chemical vapor deposition (Thermal CVD). Specifically, by supplying a silane precursor (e.g., SiH₄, Si₂H₆, Si₃H₈ and Si₄H₁₀) together with a catalyst, an amorphous silicon film may be selectively deposited on the first seed layer 151 (see FIG. 5A) as the first dielectric layer 150′ at a relatively low temperature. The thermal chemical deposition process may be performed in a chamber at, for example, room temperature to 450° C. For example, the catalyst may include diborane (B₂H₆) or phosphine (PH₃).

The selective deposition may be performed on surfaces of the first mask pattern MP1 on which the first seed layer 151 is formed, and specifically, the dielectric portions selectively grown on opposing surfaces of the first mask pattern MP1 may be merged with each other. In this case, the dielectric layer 150′ may be overgrown to the upper region of the second electrode layer 142 and may have an extending portion 150E on a lower level than that of lower surfaces of the first mask patterns MP1, in the third direction D3 relative to the surface of the substrate 101. In an example embodiment, a bottom of the extending portion 150E may include a first merging line ML1 having a concave shape extending in the first direction D1. As illustrated in FIG. 4E and FIG. 5C, the dielectric layer 150′ may be merged between the first mask patterns MP1, thereby providing a first air gap AG1 extending in the first direction D1 in a space between the stack lines 140L.

An example of the selective deposition process exemplifies depositing amorphous silicon as the first dielectric layer 150′, but the present disclosure is not limited thereto, and in some example embodiments, the first dielectric layer 150′ may be formed of silicon nitride or aluminum oxide.

The first dielectric layer 150′ may be deposited on the seed layer 151, while the first dielectric layer 150′ may be barely deposited on the side surfaces of the stack lines 140L on which the first seed layer 151 is barely formed, or may be deposited with a significantly thin thickness (about 30 Å or less) even if it is formed. Specifically, the first dielectric layer 150′ may barely be grown on the side surfaces of the selector layer 145.

Referring to FIG. 4F, the plurality of first mask patterns MP1 (see FIG. 4E) may be removed from the upper surface of the plurality of stack lines 140L. Accordingly, the first gap-covering dielectric 150 covering the first air gap AG1 may be provided.

A removal process of the first mask pattern MP1 may be performed by a CMP process, although embodiments are not limited thereto. The CMP process may be performed until the upper surface of the stack lines 140L is opened. By the process, portions of the first dielectric layer 150′ between the first mask patterns MP1 may be removed together with the first mask patterns MP1 from the upper surface of the stack lines 140L. As the portions of the first dielectric layer 150′ are removed, only the extending portion 150E of the first dielectric layer 150′ remains, and the remaining extending portion 150E may be provided as a first gap-covering dielectric 150 covering the first air gap AG1. An upper surface of the first gap-covering dielectric 150 may form a substantially flat surface with upper surfaces of the stack lines 140L; that is, the upper surface of the first gap-covering dielectric 150 may be coplanar with the upper surfaces of the stack lines 140L.

Next, referring to FIG. 4G, a second conductive layer 190L may be formed on the plurality of stack lines 140L and the first gap-covering dielectric 150, and second mask patterns MP2 may be formed on the second conductive layer 190L.

The second conductive layer 190L (also referred to as an ‘upper conductive layer’) for second conductive lines (also referred to as ‘upper conductive lines’) may be formed on flattened upper surfaces of the stack lines 140L and the first gap-covering dielectric 150. The second conductive layer 190L may include, for example, W, WN, Au, Ag, Cu, Al, TiAlN, Ir, Pt, Pd, Ru, Zr, Rh, Ni, Co, Cr, Sn, Zn, ITO, alloys thereof, or combinations thereof, similarly to the first conductive layer 110L.

The second mask patterns MP2 may be formed to intersect the first conductive lines 110. The second mask patterns MP2 may extend in the second direction D2 and may be separated from each other in the first direction D1. The second mask patterns MP2 may include two or more layers, similarly to the first mask patterns MP1. For example, the second mask patterns MP2 may include a lower film such as silicon nitride, and a hard mask layer such as silicon oxide or silicon carbonate, and may be patterned using a photoresist process.

Referring to FIG. 4H, a plurality of memory cell pillars MCP may be formed from each of the plurality of stack lines 140L using the second mask patterns MP2.

An etching process using the second mask patterns MP2 may be performed to form memory cell pillars MCP extending in the first direction D1 and separated from each other in the second direction D2. By this etching process, the filling insulating patterns 120 may be opened again, and a second recess RS2 may be formed on the upper surfaces of the filling insulating patterns 120 by additional etching.

In this etching process, the second conductive layer 190L may also be etched together with the stack lines 140L, so that second conductive lines 190 extending from the second conductive layer 190L in the second direction D2 may be obtained. The second conductive lines 190 may be formed to intersect with the first conductive lines 110, and may connect upper surfaces of the memory cell pillars MCP in the second direction D2. Accordingly, the memory cell pillars MCP may be arranged at the intersection of the first conductive lines 110 and the second conductive lines 190 in the first conductive lines 110 and the second conductive lines 190.

Next, referring to FIG. 4I, a second dielectric layer 160′ may be selectively deposited on surfaces of a plurality of second mask patterns MP2 and surfaces of a plurality of second conductive lines 190.

In this process, the second dielectric layer 160′ may be selectively deposited to fill a gap between the second mask patterns MP2 and the gap between the second conductive lines 190. A second air gap AG2 extending in the second direction D2 between the memory cell pillars MCP may be formed by the second dielectric layer 160′. This selective deposition process may be performed similarly to the selective deposition process described in FIG. 4E.

In an example embodiment, the second dielectric layer 160′ may be formed by a selective deposition process that is advantageous for direct deposition on the surfaces (upper surface and side surfaces) of the second mask patterns MP2 and side surfaces of the second conductive lines 190. A selective deposition adopted in an example embodiment may cause little deposition on exposed side surfaces of the memory cell pillars MCP.

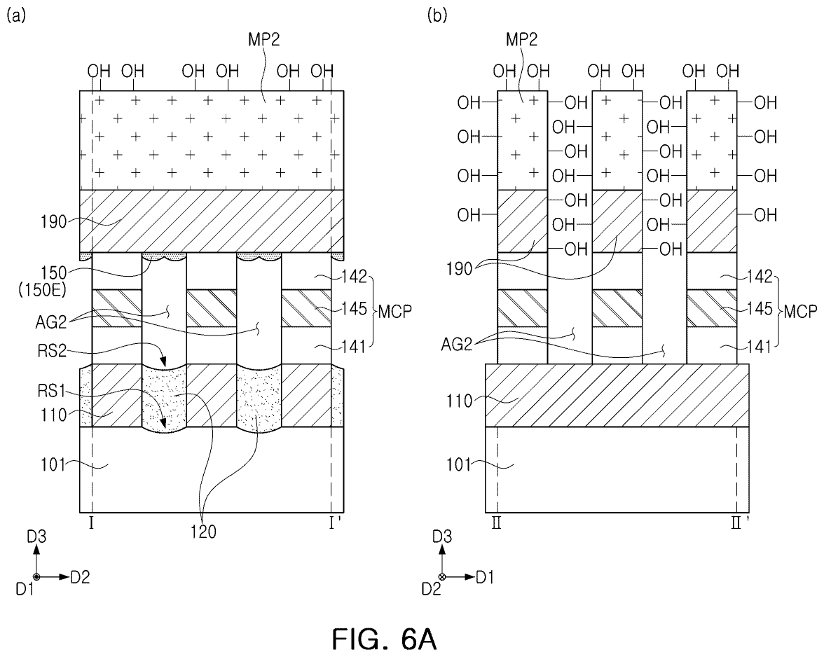

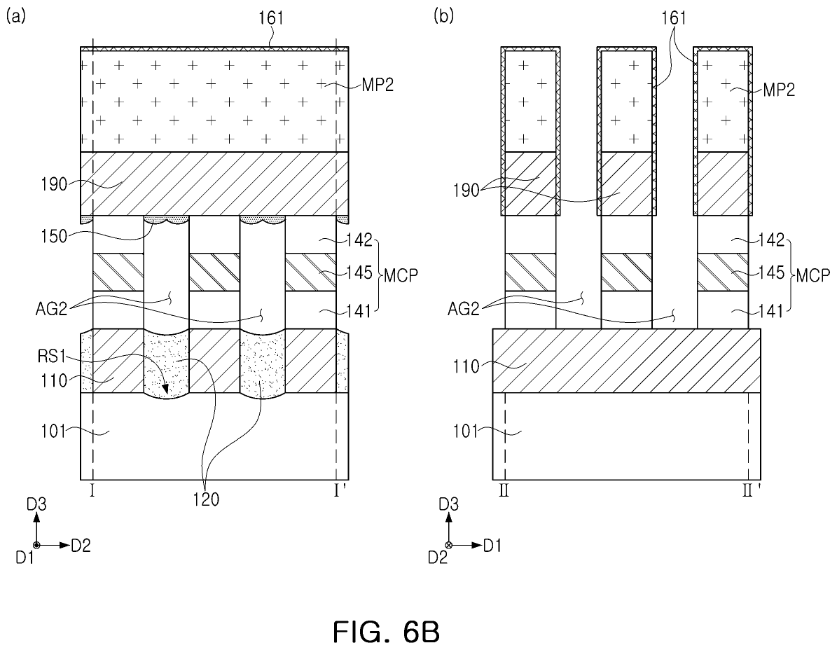

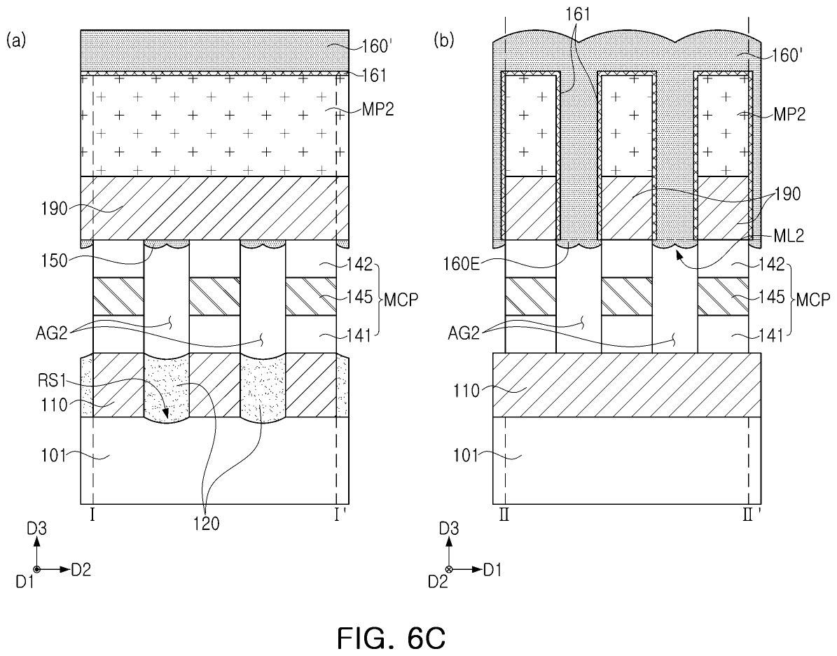

An example of a second selective deposition process that may be adopted in this process may be described in detail with reference to FIGS. 6A to 6C. FIGS. 6A and 6C may be understood as cross-sections of I-I′ and II-II′ of FIGS. 4H and 4I, respectively. This process is described as a selective deposition process in which the second dielectric layer 160′ is amorphous silicon.

First, as illustrated in FIG. 6A, in an etching process and subsequent processes for forming the memory cell pillars MCP and the second conductive lines 190, hydroxyl groups (—OH) may be adsorbed on surfaces of the second mask patterns MP2 and the second conductive lines 190. In contrast, due to the difference in the constituent materials, the side surfaces of the memory cell pillars MCP may have a small amount of hydroxyl groups (—OH) adsorbed or barely adsorbed.

As illustrated in FIG. 6B, a seed layer 161 having a different deposition rate depending on the hydroxyl groups may be selectively deposited. The second seed layer 161 may be formed on the surfaces of the second mask patterns MP2 and the second conductive lines 190 rich in hydroxyl groups (—OH). In an example embodiment, the second seed layer 161 may include a precursor for depositing amorphous silicon. In some example embodiments, the second seed layer 161 may include a silane precursor, an amine precursor, or an amine-silane precursor, identically to or similarly to the first seed layer 151.

As illustrated in FIG. 6C, the second dielectric layer 160′ which is amorphous silicon may be selectively deposited using thermochemical deposition. Specifically, by supplying a silane precursor together with a catalyst, an amorphous silicon film may be selectively deposited on the second seed layer 161 as the second dielectric layer 160′ at a relatively low temperature. The thermochemical deposition process may be performed in a chamber at, for example, room temperature to 450° C. For example, the catalyst may include diborane or phosphine.

The selective deposition may be performed on surfaces of the second mask pattern MP2 and the second conductive lines 190 on which the second seed layer 161 is formed, and specifically, dielectric portions selectively grown on the opposing surfaces of the second mask patterns MP2 and the second conductive lines 190 may be merged with each other. In some example embodiments, the second dielectric layer 160′ may be overgrown to the upper region of the second electrode layer 142. In this example embodiment, the second dielectric layer 160′ may have an extending portion on a level lower than that of the lower surfaces of the second mask patterns MP2, in the third direction D3 relative to the surface of the substrate 101, similarly to the first dielectric layer 150′, but the present disclosure is not limited thereto.

In an example embodiment, a bottom of the second dielectric layer 160′ may include a second merging line ML2 having a concave shape extending in the second direction D2. As illustrated in FIG. 4I and FIG. 6C, the second dielectric layer 160′ may be merged between the second mask patterns MP2, so that the second air gap AG2 extending in the second direction D2, among the air gaps AG, between the memory cell pillars MCP, may be provided.

An example of the selective deposition process exemplifies the deposition of amorphous silicon as the second dielectric layer 160′, but the present disclosure is not limited thereto, but in some example embodiments, the second dielectric layer 160′ may be formed of silicon nitride or aluminum oxide.

The second dielectric layer 160′ may be deposited on the second seed layer 161, while the second dielectric layer 160′ is barely deposited on the side surfaces of the memory cell pillars MCP in which a second seed layer 161 is barely formed, or the second dielectric layer 160′ may be formed with a significantly thin thickness (about 30 Å or less) even if it is deposited. Specifically, the second dielectric layer 160′ may barely be grown on side surfaces of the selector layer 145.

Next, the second gap-covering dielectric 160 may be formed by removing the second mask patterns MP2 and a portion of the second dielectric layer 160′ between the second mask patterns MP2. Accordingly, the semiconductor device 100 illustrated in FIG. 1 may be manufactured.

A process of removing the second mask pattern MP2 may be performed by a CMP process. The CMP process may be performed until the upper surfaces of the memory cell pillars MCP are opened. Through the process, the second mask patterns MP2 and the portions of the second dielectric layer 160′ between the second mask patterns MP2 may also be removed. As the portions of the second dielectric layer 160′ are removed, a portion of the second dielectric layer 160′ between the second conductive lines 190 remains, and the remaining portion may be provided as a second gap-covering dielectric 160 covering the second air gap AG2. The upper surface of the second gap-covering dielectric 160 may form a substantially flat coplanar surface with upper surfaces of the second conductive lines 190.

In the above-described embodiment, the gap-covering dielectric GD has been described with a focus on a form in which the gap-covering dielectric GD is formed in an upper structure of the semiconductor memory device 100, that is, partial lower portions of the second conductive lines 190 and a gap between the second conductive lines 190, in some example embodiments, during the selective deposition process for the gap-covering dielectric, the dielectric may also be formed in other regions of the semiconductor memory device, for example, the exposed surfaces of the filling insulating pattern and/or the first conductive lines.

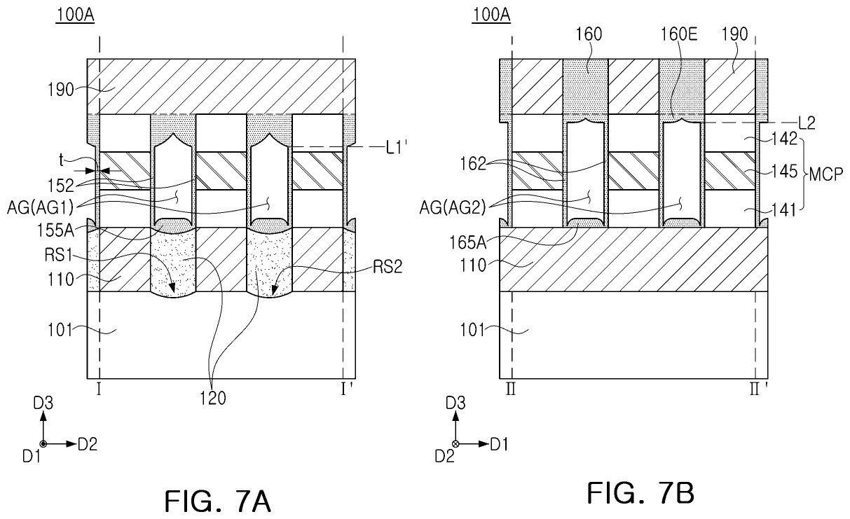

FIGS. 7A and 7B are schematic .cross-sectional views illustrating a semiconductor memory device according to an example embodiment of the present disclosure, respectively.

Referring to FIGS. 7A and 7B, a semiconductor memory device 100A according to an example embodiment may be understood as being similar to the semiconductor memory device 100 illustrated in FIGS. 1 to 3B, except that a first bottom dielectric 155A is formed on a bottom of the first air gap AG1, a second bottom dielectric 165A is formed on a bottom of the second air gap AG1, and relatively thin sidewall dielectrics 152 and 162 are formed on sidewalls of the memory cell pillars MCP. Additionally, unless otherwise specifically described, the components of this example embodiment may be understood by referring to the description of the identical or similar components of the semiconductor memory device 100 illustrated in FIGS. 1 to 3B.

The semiconductor memory device 100A according to an example embodiment may include the first bottom dielectric 155A on the bottom of the first air gap AG1 and the second bottom dielectric 165A on the bottom of the second air gap AG2. The first bottom dielectric 155A may extend in the first direction D1 on the filling insulating patterns 120, and the second bottom dielectric 165A may extend in the second direction D2 between the memory cell pillars MCP. The second bottom dielectric 165A may extend in the second direction D2 across a bottom region corresponding to the second gap-covering dielectric 160, that is, portions of the first conductive lines 110 and portions of the filling insulating patterns 120.

The first and second bottom dielectrics 155A and 165A may be formed in a process of selectively depositing the first and second gap-covering dielectrics 150 and 160, respectively.

For example, the first bottom dielectric 155A may be formed in a process of selectively depositing the first dielectric layer 150′ of FIG. 4E. A large amount of hydroxyl groups may be adsorbed on the exposed filling insulating patterns 120 on the bottom of the first air gap AG1 (see FIG. 5A), and the first seed layer 151 may be formed on the exposed filling insulating patterns 120 (see FIG. 5B). Accordingly, the same dielectric material may be deposited on the exposed filling insulating patterns 120 during the process of forming the first dielectric layer 150′, thereby forming the first bottom dielectric 155A (see FIG. 5C). Accordingly, the first gap-covering dielectric 150 may include the same material as the first bottom dielectric 155A. However, since a gap between the first mask patterns MP1 narrows as the first dielectric layer 150′ grows, a thickness of the first bottom dielectric 155A may be smaller than a thickness grown on the surface of the first mask patterns MP1.

Similarly, the second bottom dielectric 165A may be formed in a process of selectively depositing the second dielectric layer 160′ of FIG. 4I. A large amount of hydroxyl groups may be adsorbed on the portions of the first conductive lines 110 and the portions of the filling insulating patterns 120 exposed to the bottom of the second air gap AG2 (see FIG. 6A), and the second seed layer 161 may be formed on the exposed bottom portions (see FIG. 6B). Accordingly, the same dielectric material may be deposited on the exposed portions of the first conductive lines 110 and the portions of the filling insulating patterns 120 in a process of forming the second dielectric layer 160′, thereby forming the second bottom dielectric 165A (see FIG. 6C). Accordingly, the second gap-covering dielectric 160 may include the same material as the second bottom dielectric 165A. However, since the gap between the second mask patterns MP2 narrows as the second dielectric layer 160′ grows, a thickness of the second bottom dielectric 165A may be smaller than a thickness grown on the surfaces of the second mask patterns MP2.

Additionally, relatively thin first and second sidewall dielectrics 152 and 162 may be formed on the sidewalls of the memory cell pillars MCP. The sidewall dielectrics 152 and 162 may be formed when the selectivity is relatively low in the selective deposition process introduced in FIGS. 4E and 4I. Even if the first and second sidewall dielectric layers 152 and 162 are present, the first and second sidewall dielectric layers 152 and 162 may have very thin thicknesses. The first and second sidewall dielectric layers 152 and 162 may have thicknesses smaller than thicknesses of the intentionally grown first and second gap-covering dielectric layers 150 and 160 as well as the thicknesses of the first and second bottom dielectrics 155 and 165. For example, a thickness t of the first and second sidewall dielectric layers 152 and 162 may be 30 Å or less. The thickness may be defined on a side surface of the selector layer 145. The sidewall dielectric may be further included, and the second gap-covering dielectric 160 may include the same material as the second bottom dielectric 165A. The first and second sidewall dielectric layers 152 and 162 may include the same material as the first and second cap covering dielectric layers 150 and 160.

FIGS. 8A and 8B are schematic cross-sectional views each illustrating a semiconductor memory device according to an example embodiment of the present disclosure.

Referring to FIGS. 8A and 8B, a semiconductor memory device 100B according to an example embodiment may be understood as being similar to the semiconductor memory device 100 illustrated in FIGS. 1 to 3B, except that a first bottom dielectric 155B is formed between the first conductive lines 110 instead of filling insulating patterns, a second bottom dielectric 165B is formed on portions of upper surfaces of the first conductive lines 110 between the memory cell pillars MCP, and the first gap-covering dielectric 150 and the second gap-covering dielectric 160 have different bottom levels L1′ and L2, in the third direction D3 relative to the surface of the substrate 101 as a reference. Additionally, the components of an example embodiment may be understood by referring to the description of the identical or similar components of the semiconductor memory device 100 illustrated in FIGS. 1 to 3B unless otherwise specifically described.

The semiconductor memory device 100B according to an example embodiment may include the first bottom dielectric 155B extending in the first direction D1 on the bottom of the first air gap AG1 and the second bottom dielectric 165B extending in the second direction D2 on the bottom of the second air gap AG2, similarly to the previous example embodiment (see FIGS. 7A and 7B).

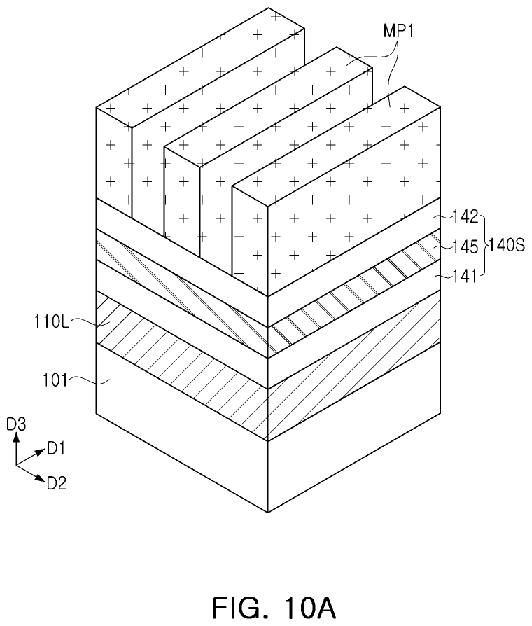

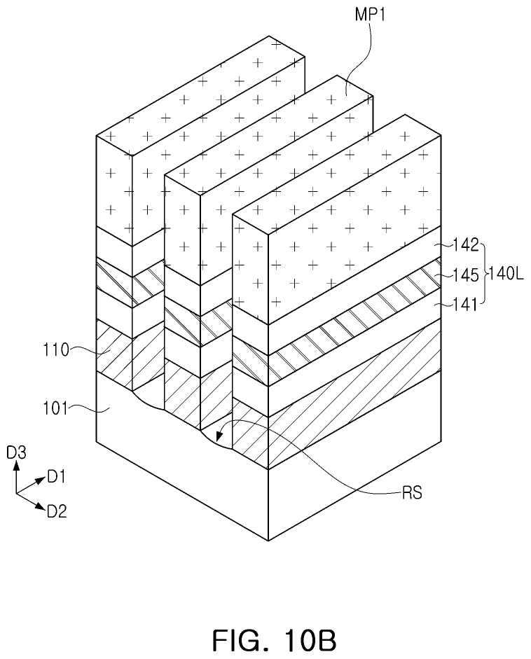

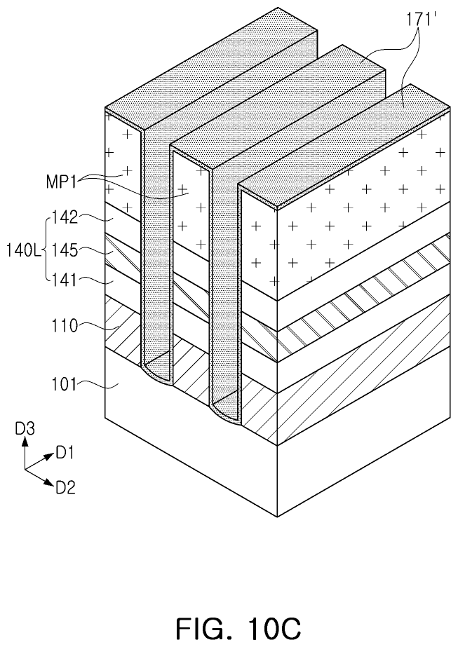

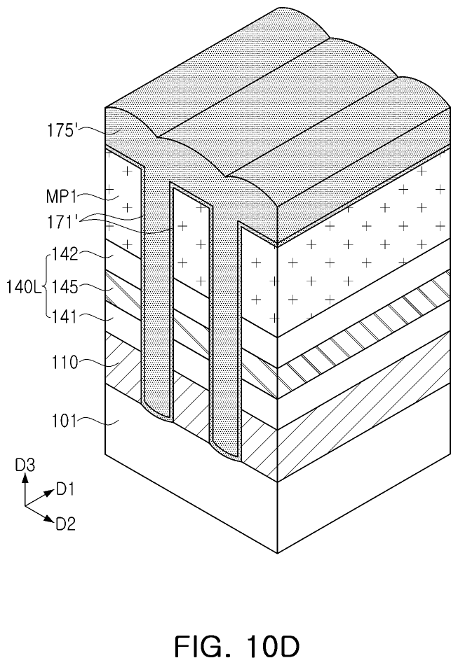

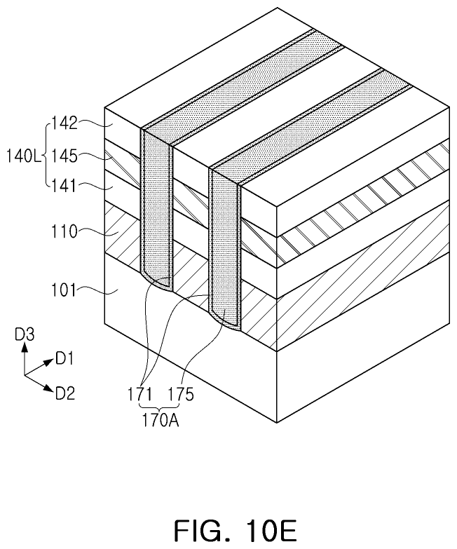

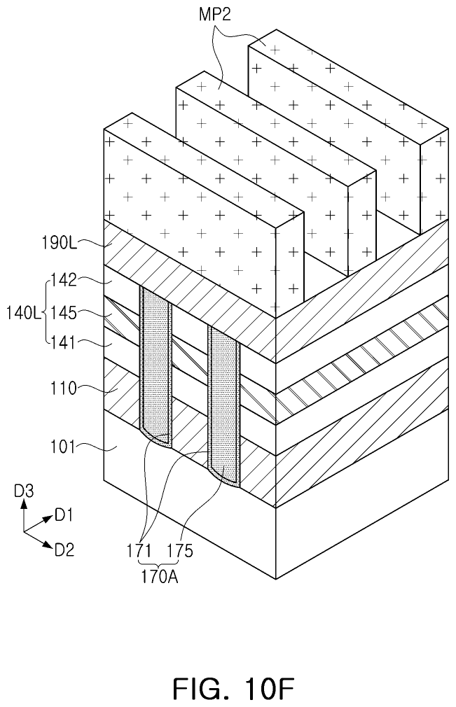

However, unlike the previous example embodiment, in an example embodiment, there are no filling insulation patterns between the first conductive lines 110, and the portions of the upper surface of the substrate 101 between the first conductive lines 110 may be exposed by the first air gap AG1. The first bottom dielectric 155B may be disposed on portions of the exposed upper surface of the substrate 101, and may extend along side surfaces of the adjacent first conductive lines 110. The structure may be obtained by etching the first conductive layer 110 together with the memory stack 140S using the first mask patterns MP1 (see FIGS. 10A and 10B). Additionally, the first and second bottom dielectrics 155B and 165B may be formed together in a process of selectively depositing the first and second gap-covering dielectrics 150 and 160, respectively, similarly to the previous example embodiment (see FIGS. 7A and 7B),

In an example embodiment, the bottoms of the first gap-covering dielectric 150 and the second gap-covering dielectric 160 may be disposed on the different bottoms L1′ and L2. Since the first gap-covering dielectric 150 and the second gap-covering dielectric 160 are formed by separate selective deposition processes, the first gap-covering dielectric 150 and the second gap-covering dielectric 160 may have different bottom levels L1′ and L2 in the third direction D3, relative to the surface of the substrate 101. As described above, the first gap-covering dielectric 150 corresponds to a portion overgrown to be lower than lower surfaces of the first conductive lines 110, a thickness of the first gap-covering dielectric 150 may be greater than the overgrown portion of the second gap-covering dielectric 160 so as to form the first gap-covering dielectric 150 having a sufficient thickness,

In the example embodiments described above, the semiconductor memory devices 100, 100A and 100B are exemplified as including the first air gap AG1 extending in the first direction D1 between the memory cell pillars MCP and the second air gap AG2 extending in the second direction D2 between the memory cell pillars MCP by introducing the first and second gap-covering dielectrics, but in some example embodiments, the air gap in one direction may be replaced with an encapsulation structure.

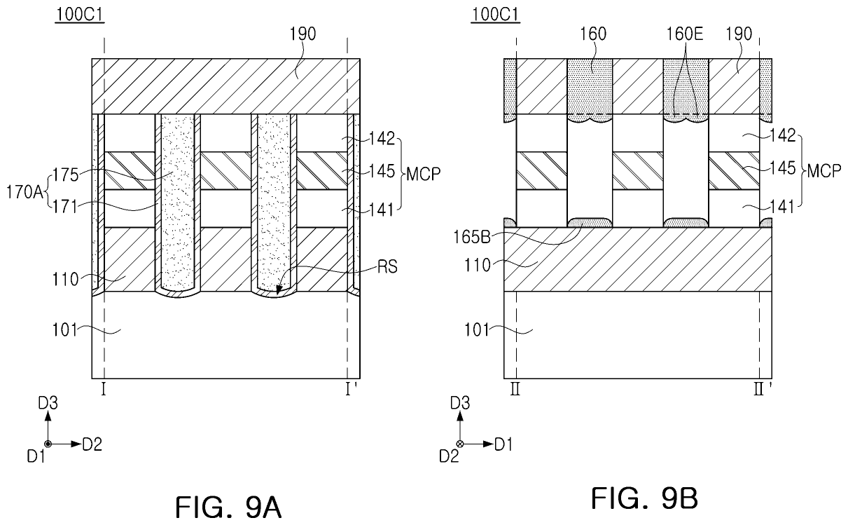

FIGS. 9A and 9B are schematic cross-sectional views respectively illustrating a semiconductor memory device according to an example embodiment of the present disclosure.

Referring to FIGS. 9A and 9B, a semiconductor memory device 100C1 according to the present embodiment may be understood as being similar to the semiconductor memory device 100 illustrated in FIGS. 1 to 3B, except that the semiconductor memory device 100C1 includes an encapsulation 170A filled in the first direction D1 between memory cell pillars MCP, the encapsulation 170A extends between the first conductive lines 110, and a bottom dielectric 165B is formed on portions of the upper surfaces of the first conductive lines 110 between the memory cell pillars MCP. Additionally, the components of this example embodiment may be understood by referring to the description of the identical or similar components of the semiconductor memory device 100 illustrated in FIGS. 1 to 3B, unless otherwise specifically described.

The semiconductor memory device 100C1 according to an example embodiment may include the encapsulation 170A filled in the first direction D1 between the memory cell pillars MCP instead of the first air gap of the previous example embodiments. The encapsulation 170A may include a capping liner 171 formed along side surfaces of the memory cell pillars MCP, the side surfaces opposing each other in the second direction D2, and a gapfill layer 175 on the capping liner 171 and at least partially filling a space between adjacent first conductive lines 110 and memory cell pillars MCP. For example, the capping liner 171 may include silicon nitride. Additionally, for example, the gapfill layer 175 may include silicon oxide or silicon oxycarbide.

The encapsulation 170A adopted in this example embodiment may extend between the first conductive lines 110 and may be connected to the upper surface of the substrate 101. The encapsulation 170A may be continuously disposed in the first direction D1 between the first conductive lines 110, but may be disposed only between the memory cell pillars MCP in a region higher than upper surfaces of the first conductive lines 110. Specifically, portions disposed between the memory cell pillars MCP of the encapsulation 170A may be separated from each other in the first direction D1 by the second air gap AG2. In some example embodiments, the gapfill layer 175 may be Flowable Oxide (FOX).

FIGS. 10A to 10F are schematic perspective views for each main process depicting intermediate processes in an example method of manufacturing the semiconductor memory device illustrated in FIGS. 9A and 9B.

Referring to FIG. 10A, a first conductive layer 110L and a memory stack 140S may be sequentially formed on the substrate 101, and first mask patterns MP1 may be formed on the memory stack 140S.

The first conductive layer 110L may be formed on the substrate 101, and a first electrode layer 141, a selector layer 145 and a second electrode layer 142 may be sequentially formed on the first conductive layer 110L in the third direction D3, thereby forming a memory stack 140S. Similarly to the process of FIG. 4C, first mask patterns MP1 may be formed on the memory stack 140S. The first mask patterns MP1 may have a pattern corresponding to the first conductive lines 110 (see FIG. 10B). The first mask patterns MP1 may extend in the first direction D1 and may be separated from each other in the second direction D2.

Next, referring to FIG. 10B, a plurality of stack lines 140L and a plurality of first conductive lines 110 may be formed using the first mask patterns MP1.

An etching process using the first mask patterns MP1 may be performed to form the stack lines 140L extending in the first direction D1 and separated from each other in the second direction D2. Through this etching process, the first conductive layer 110L may be separated, in the second direction, into the first conductive lines 110 extending in the first direction D1. Through this etching process, a recess RS may be formed in a portion between the first conductive lines 110 on the upper surface of the substrate 101.

In a process according to an example embodiment, an encapsulation 170A (see FIG. 9A) filling a gap between the stack lines 140L may be formed.

First, referring to FIG. 10C, the capping liner 171′ may be deposited on the side surfaces of the stack lines 140L and the first conductive lines 110.

The capping liner 171′ may be conformally deposited and may be formed together on side surfaces and upper surfaces of the first mask patterns MP1. The term “conformally” (or “conformal,” or like terms), in the context of a material layer or coating, is intended to refer broadly to a material layer or coating having a substantially uniform cross-sectional thickness relative to the contour of a surface to which the material layer is applied. Since a material (e.g., OTS) forming the selector layer 145 may undergo a composition change at a temperature of about 300 degrees or higher, a plasma deposition process such as Plasma Enhanced Chemical Vapor Deposition (PE-CVD) may be utilized. Next, referring to FIG. 10D, a gapfill layer 175′ may be formed on the capping liner 171′ so that the gap between the stack lines 140L is filled. The gapfill layer 175′ may be filled to form an encapsulation 170A′ between the stack lines 140L.

Next, referring to FIG. 10E, the plurality of first mask patterns MP1 may be removed from upper surfaces of the plurality of stack lines 140L.

A removal process of the first mask pattern MP1 may be performed by a CMP process. The CMP process may be performed until the upper surfaces of the stack lines 140L are opened. By this process, portions of the encapsulation 170A between the first mask patterns MP1 and the first mask patterns MP1 may be removed from the upper surface of the stack lines 140L. An upper surface of the encapsulation 170A may form a substantially flat surface with the upper surfaces of the stack lines 140L. Since the gap between the stack lines 140L is filled by the encapsulation 170A, the present CMP process may be performed more stably than the CMP process of FIG. 4F.

Next, referring to FIG. 10F, a second conductive layer 190L may be formed on the plurality of stack lines 140L and the encapsulation 170A, and second mask patterns MP2 may be formed on the second conductive layer 190L. Next, similarly to the process of FIGS. 4H to 4I, second conductive lines 190 and memory cell pillars MCP may be formed using the second mask patterns MP2, and a second gap-covering dielectric 160 may be formed between the second conductive lines 190, so that a second air gap AG2 extending in the second direction and a second gap-covering dielectric 160 covering the second air gap AG2 may be formed, as illustrated in FIG. 9B. In the case of the plasma deposition process that may be introduced in FIG. 10C, elements of reaction gases such as H₂, N₂, O₂ and NH₃ may penetrate through the selector layer 145 as impurities and may degrade the electrical characteristics of the semiconductor memory device, but since the selective deposition process may be performed as a thermochemical deposition process as described above, it may be possible to prevent performance degradation due to impurity penetration of the selector layer 145.

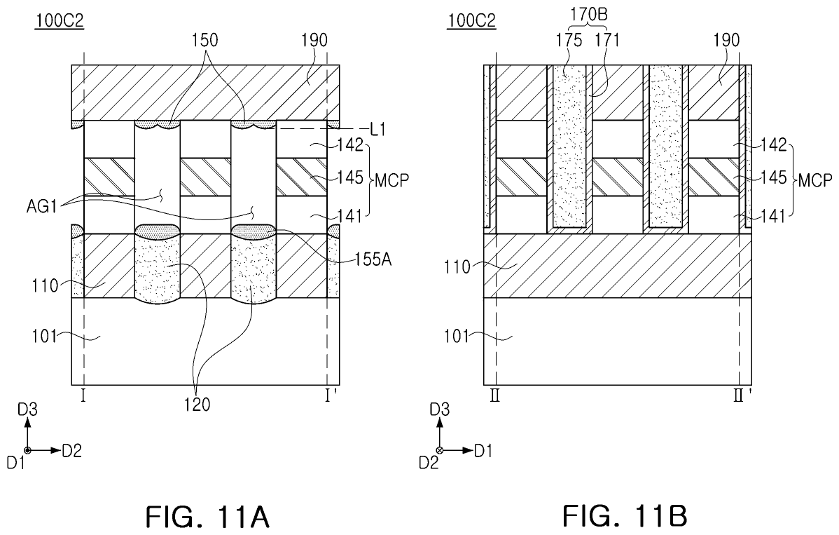

FIG. 11A and FIG. 11B are schematic cross-sectional views illustrating a semiconductor memory device according to an example embodiment of the present disclosure, respectively.

Referring to FIGS. 11A and 11B, a semiconductor memory device 100C2 according to an example embodiment may be understood as being similar to the semiconductor memory device 100 illustrated in FIGS. 1 to 3B, except that an encapsulation 170B filled in the second direction D2 is included between the memory cell pillars MCP and a bottom dielectric 155A is formed on the filling insulating patterns 120 between the memory cell pillars MCP. Additionally, the components of this example embodiment may be understood by referring to the description of the identical or similar components of the semiconductor memory device 100 illustrated in FIGS. 1 to 3B unless otherwise specifically described.

The semiconductor memory device 100C2 according to an example embodiment may include the first bottom dielectric 155A on the bottom of the first air gap AG1. The first bottom dielectric 155A may be formed in the first direction D1 on the filling insulating patterns 120, but may be separated into a plurality of portions by the encapsulation 170B extending in the second direction D2. In an example embodiment, the separated portions of the first bottom dielectric 155A may be respectively disposed on portions of the filling insulating patterns 120 between the memory cell pillars MCP.

In an example embodiment, instead of the second air gap, the encapsulation 170B filled in the second direction D1 may be included between the memory cell pillars MCP. The encapsulation 170B may include a capping liner 171 formed along side surfaces of the memory cell pillars MCP, the side surfaces opposing each other in the first direction D1, and a gapfill layer 175 on the capping liner 171 at least partially filling a space between the memory cell pillars MCP and the second conductive lines 190. The encapsulation 170B adopted in this example embodiment may separate the second conductive lines 190 from each other in the first direction D1.

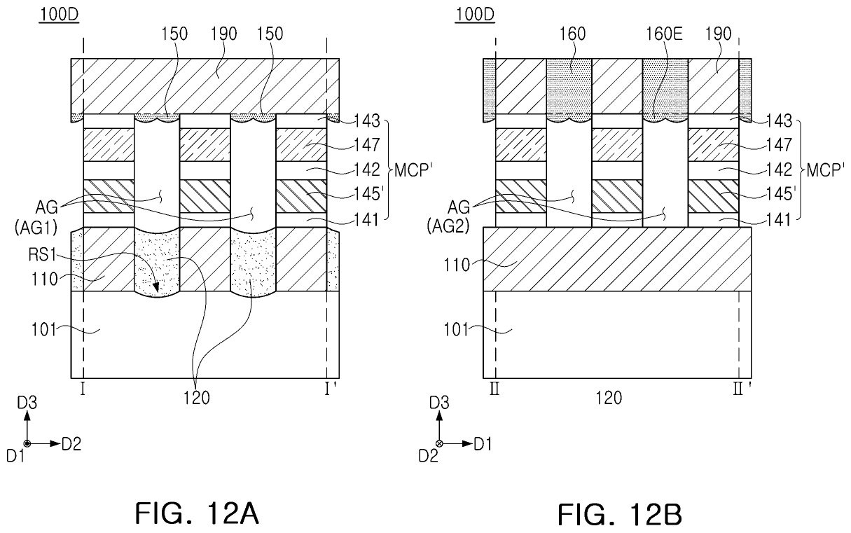

FIGS. 12A and 12B are schematic cross-sectional views each illustrating a semiconductor memory device according to an example embodiment of the present disclosure.

Referring to FIGS. 12A and 12B, a semiconductor memory device 100D according to an example embodiment may include memory cell pillars MCP′ having a selector layer 145′ and an information storage layer 147 electrically connected to each other. Additionally, the memory cell pillars MCP′ may be arranged at an intersection of the first and second conductive lines 110 and 190, respectively, between the first and second conductive lines 110, 190.

In the memory cell pillars MCP′, the selector layer 145′ and the information storage layer 147 may be disposed to be connected in series in a third direction D3, and the selector layer 145′ may be connected to the first conductive line 110 by the first electrode layer 141. The information storage layer 147 may be connected to the second conductive line 190 by a third electrode layer 143, and the selector layer 145′ and the information storage layer 147 may be connected by the second electrode layer 142.

Each of the information storage layers 147 may include a phase change material. For example, the phase change material may include selenium (Se) and/or tellurium (Te), and may include one or two or more elements selected from Ge, Sb, Bi, Pb, Sn, Ag, As, S, Si, In, Ti, Ga, P, B, O and C. The phase change material may include Ge—Sb—Te (GST). For example, Ge—Sb—Te (GST) may be a compound including Ge, Sb, and Te, and may include Ge₂Sb₂Te₅, Ge₂Sb₂Te₇, GeSb₂Te₄, and/or GeSb₄Te₇. The phase change material may further include one or two or more metal elements selected from aluminum (Al), zinc (Zn), chromium (Cr), manganese (Mn), iron (Fe), cobalt (Co), nickel (Ni), molybdenum (Mo), ruthenium (Ru), palladium (Pd), hafnium (Hf), tantalum (Ta), iridium (Ir), platinum (Pt), zirconium (Zr), thallium (Tl), and polonium (Po).

The selector layer 145′ may include an OTS material as described in the previous example embodiment (see FIGS. 1, 2A, and 2B). For example, the selector layer 145′ may include a chalcogenide material.

The semiconductor memory device 100D according to an example embodiment may include first and second gap-covering dielectrics 150 and 160. The first gap-covering dielectric 150 may include patterns respectively disposed on portions of the lower surfaces of the second conductive lines 190 disposed between the plurality of memory cell pillars MCP in the second direction D2. The second gap-covering dielectric 160 may extend between the second conductive lines 190 in the second direction D2. The second gap-covering dielectric 160 may fill a gap between the second conductive lines 190, similarly to the filling insulating patterns 120.

The first and second gap-covering dielectrics 150 and 160 according to an example embodiment may be formed by selective deposition using a thermochemical deposition process. In some example embodiments, the first gap-covering dielectric 150 and the second gap-covering dielectric 160 may be formed using a seed layer capable of selective deposition in a region rich in hydroxyl groups (—OH). At least one of the first gap-covering dielectric 150 and the second gap-covering dielectric 160 may be formed of amorphous silicon, silicon nitride, or aluminum oxide. The first gap-covering dielectric 150 and the second gap-covering dielectric 160 may include the same material, but may be formed by different deposition processes, and thus, in some example embodiments, the first gap-covering dielectric 150 and the second gap-covering dielectric 160 may be formed of different materials.

The semiconductor device 100D according to an example embodiment may have first and second air gaps AG1 and AG2 between the plurality of memory cell pillars MCP by the first and second gap-covering dielectrics 150 and 160, and the air gap AG may prevent interference between adjacent memory cell pillars MCP. The air gap AG may effectively suppress crosstalk between the memory cell pillars MCP.

In an example embodiment, there may be no dielectric on the side surfaces of the memory cell pillar MCP. For example, side surfaces of the selector layer 145′ and the information storage layer 147 may be exposed to the air gap AG. In some example embodiments, depending on the selectivity of the selective deposition, a side wall dielectric layer (“152” or “162” in FIGS. 8A and 8B) may also be formed on the side surfaces of the memory cell pillar MCP′ when the first and second gap-covering dielectrics 150 and 160 are formed, but even if the side wall dielectric layer is present, the side wall dielectric layer may have a significantly thin thickness (e.g., less than 30 Å) (see FIGS. 8A and 8B).

According to example embodiments described above, a gap-covering dielectric providing an air gap between memory cell pillars may be formed using a selective deposition process. A plasma deposition process may prevent detrimental effects such as impurity penetration into a selector layer using a selective deposition process. In addition, crosstalk between memory cell pillars may be suppressed by providing an air gap.

Advantages and effects of the present application are not limited to the foregoing content and may be more easily understood in the process of describing a specific example embodiment of the present disclosure. The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A method of manufacturing a semiconductor device, comprising:
forming a memory stack including a selector layer;
forming a plurality of first mask patterns on the memory stack, the plurality of first mask patterns each extending in a first direction parallel to a surface of the memory stack and separated from each other in a second direction, parallel to the surface of the memory stack and intersecting the first direction;
forming a plurality of stack lines extending in the first direction, by etching the memory stack using the plurality of first mask patterns;
selectively depositing a first dielectric layer on surfaces of the plurality of first mask patterns so that a first air gap between the plurality of stack lines is formed by filling a gap between the plurality of first mask patterns, the first dielectric layer having an extending portion extending between the plurality of stack lines below bottom surfaces of the plurality of first mask patterns;
removing the plurality of first mask patterns and a portion of the first dielectric layer between the plurality of first mask patterns, from upper surfaces of the plurality of stack lines, the extending portion of the first dielectric layer being provided as a first gap-covering dielectric on the first air gap;
forming an upper conductive layer on the plurality of stack lines and the first gap-covering dielectric;
forming a plurality of second mask patterns on the upper conductive layer, each of the plurality of second mask patterns extending in the second direction and separated from each other in the first direction;
forming a plurality of memory cell pillars and a plurality of upper conductive lines, by etching each of the plurality of stack lines and the upper conductive layer using the plurality of second mask patterns, each of the plurality of upper conductive lines connecting respective memory cell pillars of the plurality of memory cell pillars in the second direction;
selectively depositing a second dielectric layer on surfaces of the plurality of second mask patterns and surfaces of the plurality of upper conductive lines so that a second air gap extending in the second direction is formed between the plurality of memory cell pillars by filling respective gaps between the plurality of second mask patterns and respective gaps between the plurality of upper conductive lines; and
removing the plurality of second mask patterns and a portion of the second dielectric layer between the plurality of second mask patterns, a portion of the second dielectric layer between the plurality of upper conductive lines being provided as a second gap-covering dielectric on the second air gap.

2. The method of manufacturing a semiconductor device of claim 1,
wherein at least one of selectively depositing the first dielectric layer or selectively depositing the second dielectric layer includes:
selectively depositing a seed layer having a deposition rate that is a function of a hydroxyl group; and
depositing a dielectric material on the seed layer.

3. The method of manufacturing a semiconductor device of claim 2,
wherein the seed layer includes at least one of a silane-based precursor, an amine-based precursor, or an aminosilane-based precursor.

4. The method of manufacturing a semiconductor device of claim 2,
wherein the dielectric material includes amorphous silicon.

5. The method of manufacturing a semiconductor device of claim 1,
wherein the extending portion of the first gap-covering dielectric is disposed above an upper surface of the selector layer.

6. The method of manufacturing a semiconductor device of claim 1,
wherein in selectively depositing the first dielectric layer and the second dielectric layer, the first dielectric layer and the second dielectric layer are not grown from a side surface of the selector layer.

7. The method of manufacturing a semiconductor device of claim 1,
wherein at least one of the first dielectric layer or the second dielectric layer includes a portion disposed on sidewalls of the plurality of memory cell pillars, and
the portion on the sidewalls of the plurality of memory cell pillars has a thickness of about 30 Å or less.

8. The method of manufacturing a semiconductor device of claim 1,
wherein a bottom of the first gap-covering dielectric and a bottom of the second gap-covering dielectric are disposed on different levels in the third direction, relative to the surface of the memory stack.

9. The method of manufacturing a semiconductor device of claim 1,
wherein the second gap-covering dielectric has an extending portion extending below bottom surfaces of the plurality of upper conductive lines in the third direction.

10. The method of manufacturing a semiconductor device of claim 1, further comprising, before forming the memory stack:
forming a lower conductive layer on a substrate;
forming a plurality of lower conductive lines extending in the first direction by separating the lower conductive layer in the second direction; and
forming a filling insulating pattern filling a gap between the plurality of lower conductive lines.

11. The method of manufacturing a semiconductor device of claim 10,
wherein selectively depositing the first dielectric layer includes:
depositing a dielectric material on a first portion of the filling insulating pattern disposed on a bottom of the first air gap.

12. The method of manufacturing a semiconductor device of claim 10,
wherein selectively depositing the second dielectric layer includes:
depositing a dielectric material on a second portion of the filling insulating pattern disposed on a bottom of the second air gap and a portion of the plurality of lower conductive lines.

13. The method of manufacturing a semiconductor device of claim 1, further comprising forming a lower conductive layer on a substrate, before the forming the memory stack,
wherein forming the plurality of stack lines includes:
forming a plurality of lower conductive lines together with the plurality of stack lines, by separating the lower conductive layer and the plurality of stack lines in the second direction.

14. The method of manufacturing a semiconductor device of claim 10,
wherein selectively depositing the first dielectric layer includes:
depositing a dielectric material on a side surface of each of the plurality of lower conductive lines exposed to the first air gap.

15. A method of manufacturing a semiconductor device, comprising:
forming a lower conductive layer on a substrate, and forming a memory stack including a selector layer on the lower conductive layer;
forming a plurality of first mask patterns on the memory stack, each of the plurality of first mask patterns extending in a first direction parallel to a surface of the substrate and separated from each other in a second direction parallel to the surface of the substrate and intersecting the first direction;
forming a plurality of stack lines and a plurality of lower conductive lines, by etching the memory stack and the lower conductive layer using the plurality of first mask patterns;
forming an encapsulation between the plurality of stack lines and between the plurality of lower conductive lines;
removing the plurality of first mask patterns to expose respective upper surfaces of the plurality of stack lines;
forming an upper conductive layer on the plurality of stack lines and the encapsulation;
forming a plurality of second mask patterns on the upper conductive layer, each of the plurality of second mask patterns extending in the second direction and separated from each other in the first direction;
forming a plurality of memory cell pillars and a plurality of upper conductive lines, by etching each of the plurality of stack lines together with the upper conductive layer using the plurality of second mask patterns, each of the plurality of upper conductive lines connecting the plurality of memory cell pillars in the second direction;
selectively depositing a dielectric layer on respective surfaces of the plurality of second mask patterns and respective surfaces of the plurality of upper conductive lines so that an air gap extending in the second direction is formed between the plurality of memory cell pillars by filling a gap between the plurality of second mask patterns and a gap between the plurality of upper conductive lines; and
removing the plurality of second mask patterns and a portion of the dielectric layer between the plurality of second mask patterns, a portion of the dielectric layer between the plurality of upper conductive lines being provided as a gap-covering dielectric on the air gap.

16. The method of manufacturing a semiconductor device of claim 15,
wherein the dielectric layer includes amorphous silicon, silicon nitride, or aluminum oxide.

17. The method of manufacturing a semiconductor device of claim 15,
wherein a bottom of the gap-covering dielectric is at a level higher, in a third direction perpendicular to the surface of the substrate, than an upper surface of the selector layer, relative to the surface of the substrate.

18. The method of manufacturing a semiconductor device of claim 15,
wherein the dielectric layer is not present on a side surface of the selector layer, or the dielectric layer, if present on the side surface of the selector layer, has a thickness of about 30 Å or less.

19. The method of manufacturing a semiconductor device of claim 15,
wherein selectively depositing the dielectric layer includes:
depositing a dielectric material on a portion of a filling insulating pattern disposed on a bottom of the air gap and portions of the plurality of lower conductive lines.

20. A method of manufacturing a semiconductor device, comprising:
forming a memory stack including a selector layer;
forming a plurality of first mask patterns on the memory stack, each of the plurality of first mask patterns extending in a first direction parallel to a surface of the memory stack and separated from each other in a second direction parallel to the surface of the memory stack and intersecting the first direction;
forming a plurality of stack lines extending in the first direction, by etching the memory stack using the plurality of first mask patterns;
selectively depositing a dielectric layer on surfaces of the plurality of first mask patterns to fill a gap between the plurality of first mask patterns and form an air gap between the plurality of stack lines, the dielectric layer having an extending portion that is lower, in a third direction perpendicular to the surface of the memory stack, than a bottom level of the mask pattern, relative to the surface of the memory stack;
removing the plurality of first mask patterns and a portion of the dielectric layer between the plurality of first mask patterns, from respective upper surfaces of the plurality of stack lines, the extending portion of the dielectric layer being provided as a gap-covering dielectric on the air gap;
forming an upper conductive layer on the plurality of stack lines and the gap-covering dielectric;
forming a plurality of second mask patterns on the upper conductive layer, each of the plurality of second mask patterns extending in the second direction and separated from each other in the first direction;
forming a plurality of memory cell pillars and a plurality of upper conductive lines, by etching each of the plurality of stack lines together with the upper conductive layer using the plurality of second mask patterns, each of the plurality of upper conductive lines connecting the respective plurality of memory cell pillars in the second direction; and
forming an encapsulation between the plurality of upper conductive lines and between the plurality of memory cell pillars.
